(19) United States
(12) Patent Application Publication
(10) Pub. No.: US 2013/0049847 A1
(43) Pub. Date: Feb. 28, 2013

(54) BOOTSTRAPPING TECHNIQUES FOR CONTROL OF CMOS TRANSISTOR SWITCHES

(71) Applicant: Adam GLIBBERY, Hants (GB)

(72) Inventor: Adam GLIBBERY, Hants (GB)

(73) Assignee: ANALOG DEVICES, INC., Norwood, MA (US)

(21) Appl. No.: 13/222,229

(22) Filed: Aug. 31, 2011

(51) Int. Cl. H03K 17/687; H03K 17/00

(52) U.S. Cl. 327/543; 327/538

(57) ABSTRACT

Techniques to provide bootstrap control of a CMOS transistor switch. The techniques may include driving a control terminal of a CMOS transistor switch to a first predetermined voltage to set the CMOS transistor switch to an off-state. The first predetermined voltage may be drained to a discharge voltage and the control terminal may be driven to a second predetermined voltage to set the CMOS transistor switch to an on-state. The control terminal may be driven to the first predetermined voltage to return the CMOS transistor switch to the off-state.

### BACKGROUND

A CMOS transistor can be configured as an input switch for controlling a signal path for signals input to an integrated circuit (IC). To cause a CMOS transistor to behave as an off/on switch, control signals are applied to the transistor's gate terminal. A voltage threshold VT must be overcome to cause a CMOS input transistor to change its switching state. The voltage threshold VT is the difference between the gate terminal (V_{G}) and the source terminal (V_{S}) of the transistor. This voltage difference may be termed as the gate-source voltage (V_{GS}). For example, to cause a PMOS-type input transistor to switch to an on-state, the voltage applied to the PMOS gate V_{G} must be at least a VT below the voltage applied to the PMOS source V_{S}. To cause an NMOS-type transistor to switch to an on-state, the voltage applied to the NMOS gate V_{G} must be at least a VT above the voltage applied to the NMOS source V_{S}.

A technique to cause a PMOS input transistor to behave as an off/on switch is known as “bootstrapping” the PMOS input switch. Bootstrapping also extends the operating range for the PMOS input transistor with respect to various input signal voltages. One example of a bootstrapping circuit for a PMOS input switch is shown in FIG. 1.

As illustrated in FIG. 1, a PMOS transistor switch 110 within an IC is coupled to a bootstrapping circuit 120 which includes a PMOS transistor 130 having its source pin coupled to a supply voltage VT, its gate pin coupled to a first switch 140, and its drain pin coupled to a common node N1. The first switch 140 has selectable inputs coupled to supply voltages 2*VT and VGND (0V). A limiting diode 170 has its input coupled to common node N1 and its output coupled to the PMOS transistor switch 110 source pin. A capacitor 150 has one terminal coupled to common node N1 and another terminal coupled to a second switch 160, and the second switch 160 has selectable inputs coupled to supply voltages VDD and VGND (0V). The PMOS input switch 110 has its gate pin coupled to the common node N1, its source pin coupled both to the output of diode 170 and an input pin of the IC, and its drain pin coupled to a subsequent internal circuit within the IC.

To hold the PMOS transistor switch 110 in an off-state, the first switch 140 is set to VGND (0V) and the second switch 160 is set to VDD. The supply voltage VT is driven through transistor 130 into the common node N1. Thus, the PMOS transistor switch 110 gate-source voltage V_{GS} is set to VT. To hold the PMOS transistor switch 110 in an on-state the second switch 160 is set to VGND (0V). This drives the common node N1 voltage to VT-VDD. A condition to set the PMOS transistor switch 110 to an on-state for an input signal of 0V requires that VDD be greater than or equal to twice the threshold voltage or 2*VT.

While the bootstrapping circuit 120 described in FIG. 1 controls a PMOS transistor switch, it suffers from several limitations. First, as noted above, the bootstrapping circuit requires a supply voltage VDD≧2*VT to set a PMOS transistor switch to the on-state. As technology advances, IC supply voltages may decrease such that the above requirement cannot be maintained for a voltage threshold VT equal to 0.8V. For example, many modern ICs are designed for VDD voltage supplies of 1.3V.

Second, it may be desirable to return a PMOS transistor switch to an off-state after setting it in the on-state. However, the gate-source limiting diode (i.e., limiting diode 170 of FIG. 1) presents a short between the gate and source of a PMOS transistor switch. Any voltage that is driven into the gate pin of a PMOS transistor switch is also driven into the source pin of the input switch (less the voltage drop across the diode). Thus, it may be difficult to drive the gate pin to at least a VT above the source pin to return the PMOS transistor switch to an off-state once it has been set to the on-state.

Accordingly, there is a need in the art to provide bootstrapping techniques that may control a CMOS transistor switch which are not limited by supply voltages and may control a CMOS transistor switch to off and on-states.

### BRIEF DESCRIPTION OF THE DRAWINGS

FIG. 1 illustrates a bootstrapping circuit for control of a PMOS transistor switch.

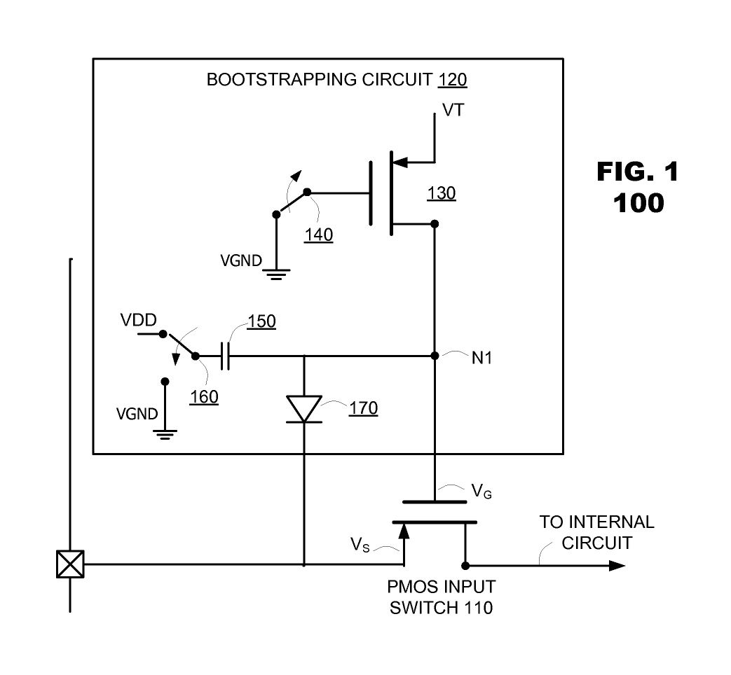

FIG. 2 illustrates a bootstrap system for controlling a transistor switch according to an embodiment of the present invention.

FIG. 3 illustrates a method for controlling a transistor to switch from an off-state to an on-state according to an embodiment of the present invention.

FIG. 4 illustrates exemplary configurations for a ground switching unit according to an embodiment of the present invention.

### DETAILED DESCRIPTION

Embodiments of the present invention provide techniques to provide bootstrap control of a CMOS transistor switch. The techniques may include driving a control terminal of the CMOS transistor switch to a first predetermined voltage to set the CMOS transistor switch to an off-state. The first predetermined voltage may be drained to a discharge voltage and the control terminal may be driven to a second predetermined voltage to set the CMOS transistor switch to an on-state. The control terminal may be driven to the first predetermined voltage to return the CMOS transistor switch to the off-state.

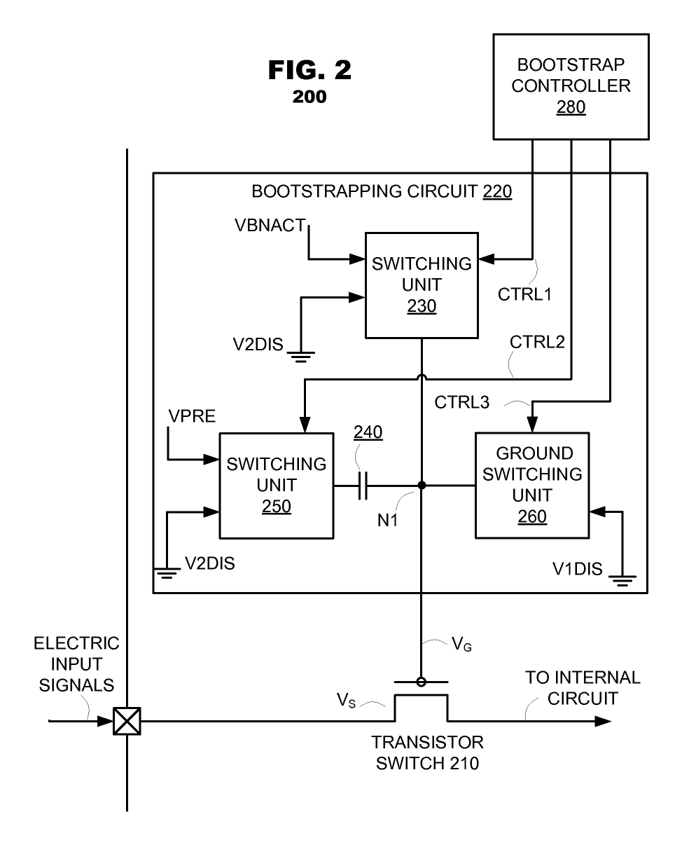

FIG. 2 illustrates a bootstrap system 200 for controlling a CMOS transistor switch 210 according to an embodiment of the present invention. As illustrated in FIG. 2, the system 200 may include a bootstrapping circuit 220 having a first switching unit 230 coupled to a bootstrap inactivation voltage VBNACT, a second discharge voltage V2DIS, and an input node N1 of the transistor input switch 210. The bootstrapping circuit 220 may further have a second switching unit 250 coupled to a precharge voltage VPRE, a second discharge voltage V2DIS, and a second terminal of a capacitor 240. The capacitor 240 may have a first terminal coupled to the input node N1 of the transistor switch 210. The bootstrapping circuit 220 may further have a ground switching unit 260 coupled to the input node N1 of the CMOS transistor switch 210 and a first discharge voltage V1DIS, and a bootstrap controller 280 having output control signals CTRL1, CTRL2, and CTRL3 coupled to the first, second, and ground switching units 230, 250, 260.

The transistor switch 210 may have its gate coupled to the input node N1. It may further have its source coupled to a pin of an IC for receiving electric input signals and its drain coupled to a subsequent internal circuit within the IC.

The bootstrapping circuit 220 may operate in three phases. A first phase may set the transistor switch 210 to an off-state thus impeding the flow of the electric input signal 270 into the internal circuit. A second phase may set the transistor switch 210 to an on-state thus allowing the electric input signal 270 to flow into the internal circuit. Finally, a third phase may return the transistor switch to the off-state.

During the first operational phase, the bootstrap controller 280 may set the first switching unit 230 to drive the bootstrap inactivation voltage VBNACT into the gate of the input switch 210 at the input node N1. The controller 280 also may set the second switching unit 250 to present the precharge voltage VPRE to the capacitor 240. Thus, the capacitor 240 may charge to the precharge voltage VPRE. Finally, the controller 280 may set the ground switching unit 260 to open, disconnecting the input node N1 from the first discharge voltage V1DIS. During the first phase, the bootstrap inactivation voltage VBNACT may hold the transistor switch 210 in an off-state. The voltage that may hold the transistor switch in the off-state may be termed an inactivation voltage.

In the second operational phase, the controller 280 may set the first switching unit 230 to remove the bootstrap inactivation voltage VBNACT from the gate of the CMOS transistor switch 210. The controller 280 may set the ground switching unit 260 to couple the input node N1 to the first discharge voltage V1DIS for a predetermined period of time allowing the bootstrap inactivation voltage VBNACT to discharge. After the expiration of the predetermined period of time, the controller 280 may set the ground switching unit 260 to open and may set the second switching unit 250 to reverse connect the second terminal of the capacitor 240 to the second discharge voltage V2DIS. Thus, the capacitor 240 first terminal (connected to input node N1) may induce the inverse of the precharge voltage on the gate of the transistor switch 210. This may set the transistor switch 210 to the on-state.

For the third operational phase, the controller 280 may set the first switching unit 230 to the off-state by driving the bootstrap inactivation voltage VBNACT into the gate of the CMOS transistor switch 210. In an embodiment, the controller 280 may set the second switching 250 unit to present the precharge voltage to the capacitor 240.

In an embodiment, the bootstrap inactivation voltage VBNACT may be at least a threshold voltage VT of the transistor switch to be controlled. In an embodiment, the precharge voltage may be at least double a threshold voltage 2VT of the transistor switch to be controlled.

In an embodiment, the CMOS transistor switch 210 may be configured as a PMOS transistor switch. In this embodiment, the bootstrap inactivation voltage VBNACT may be a threshold voltage VT of the PMOS transistor switch and the precharge voltage may be at least 2VT. In this embodiment, the first discharge voltage V1DIS and the second discharge voltage V2DIS may both be ground.

In an embodiment, the CMOS transistor switch 210 may be configured as an NMOS transistor switch. In this embodiment, the bootstrap inactivation voltage VBNACT may be a threshold voltage −VT of the NMOS transistor switch and the precharge voltage may be at least −2VT. In this embodiment, the first and second discharge voltages V1D1S, V2DIS may both be ground.

In an embodiment, the precharge voltage may be generated by a transistor amplifier circuit. In another embodiment, the precharge voltage may be generated by a transistor charge pump. In another embodiment, the precharge voltage may be generated by a collapsing amplifier. A collapsing amplifier may effectively become a switch and shut-off when the amplifier output voltage approaches a positive supply for the amplifier.

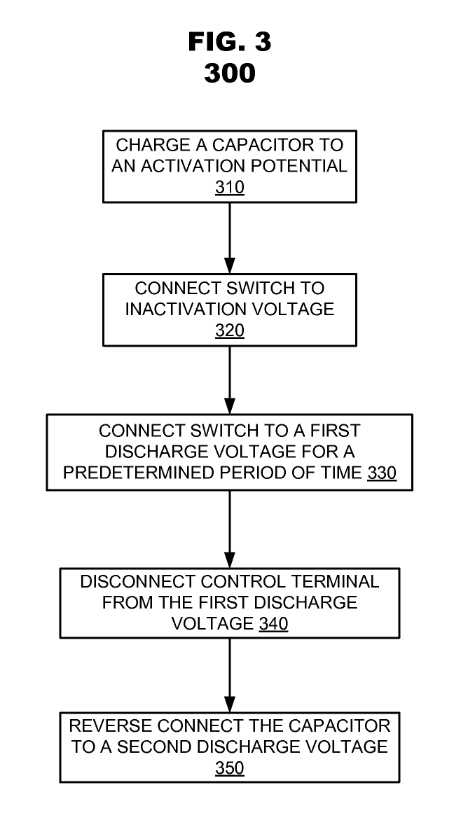

FIG. 3 illustrates a method 300 for controlling a transistor to switch from an off-state to an on-state according to an embodiment of the present invention. The method 300 may begin by charging a capacitor to an activation potential (block 310). The method may connect a transistor switch control terminal to an inactivation voltage (block 320). The method 300 may connect the control terminal to a first discharge voltage for a predetermined period of time (block 330). The method may disconnect the control terminal of the transistor switch from the first discharge voltage (block 340). The method 300 may reverse connect the capacitor to a second discharge voltage to induce the inverse of the activation potential on the control terminal (block 350).

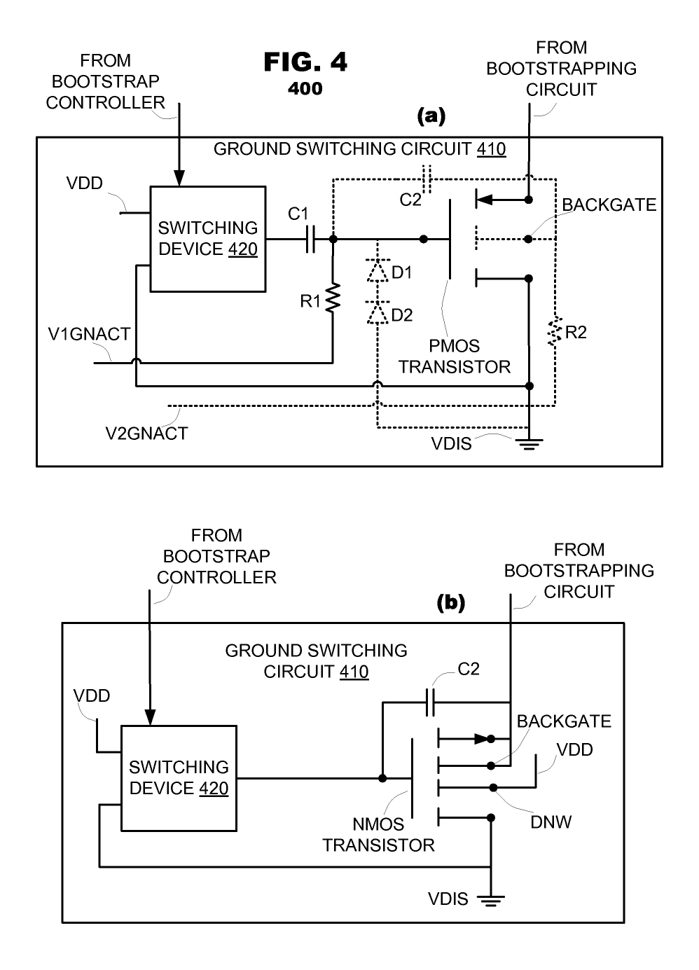

FIG. 4 illustrates exemplary configurations 400 for a ground switching unit according to an embodiment of the present invention. FIG. 4(a) illustrates a configuration for a ground switching unit 410 using a PMOS transistor switch. FIG. 4(b) illustrates a configuration for a ground switching unit 410 using a deep n-well NMOS transistor switch.

As illustrated in FIG. 4(a), a ground switching unit 410 may include a PMOS transistor switch having a gate coupled to a first terminal of a first resistor R1, a first terminal of a capacitor C1. The PMOS transistor switch may further have a source coupled to a bootstrapping circuit (not shown) and a drain coupled to a discharge voltage VDIS. The first resistor R1 may have a second terminal coupled to a first ground switch inactivation voltage V1GNACT. The capacitor C1 may have a second terminal coupled to a switching device 420 and the switching device 420 may be coupled to a positive supply voltage VDD and the discharge voltage VDIS, and may have an input coupled to a bootstrap controller (not shown).

The ground switching unit 410 may operate in two phases. In the first operational phase, the PMOS switch may remain in an off-state. Recall, from example of the first operational phase of FIG. 2 that the bootstrap inactivation voltage VBNACT may be applied to the input node N1 of the bootstrapping circuit 210. Thus, the bootstrap inactivation voltage VBNACT may be present at the source of the PMOS transistor switch during the first operational phase of the ground switching unit 410. The first ground switch inactivation voltage V1GNACT may be set to a voltage that may hold the PMOS transistor switch in the off-state while the bootstrap inactivation voltage VBNACT may be applied to the PMOS transistor switch source. The switching device 420 may be set to present the positive supply voltage VDD to the capacitor C1. In an embodiment, the switching device 420 may be configured using transistors.

In the second operational phase, the PMOS transistor switch may be set to an on-state for a predetermined time period and may then return to the off-state. For the second phase, the switching device 420 may be set to reverse connect the capacitor C1 to the discharge voltage VDIS. The voltage present at the gate of the PMOS transistor switch may be the difference between the first ground switch inactivation voltage V1GNACT and the supply voltage VDD. The voltage applied to the gate may set the PMOS transistor switch to an on-state and the bootstrap inactivation charge VBNACT that may be applied to the source of the PMOS transistor switch may dissipate.

The PMOS transistor switch may remain in an on-state for a predetermined time period. After the expiration of the predetermined time period, the switching unit 420 may be set to present the supply voltage VDD to the capacitor C1 thus, the PMOS transistor switch may be set back to the off-state.

In an embodiment, the PMOS transistor switch may further have a backgate coupled to a first terminal of the capacitor C2 and a first terminal of a second resistor R2. A second terminal of the capacitor C2 may be coupled to the PMOS transistor switch gate. In this embodiment, the second resistor R2 may have a second terminal coupled to a second ground switch inactivation voltage V2GNACT. In such an embodiment, the voltage present at the backgate of the PMOS transistor switch may be reduced to the difference between the second ground switch inactivation voltage V2GNACT and the supply voltage VDD during the second operational phase. Reducing the backgate voltage in such a manner may increase the switching efficiency for the PMOS transistor switch.

In an embodiment, the first ground switch inactivation voltage V1GNACT may be a value less than a threshold voltage of a transistor switch to be controlled (e.g., transistor switch 210 of FIG. 2) and greater than ground. In an embodiment, the second ground switch inactivation voltage V2GNACT may be set to a threshold voltage of the PMOS transistor switch. In an embodiment, the first ground switch inactivation voltage V1GNACT may be set by a first transistor amplifier circuit. In an embodiment, the second ground switch inactivation voltage V2GNACT may be set by a second transistor amplifier circuit. In another embodiment, a pair of diodes D1 and D2 may be connected between the PMOS transistor switch gate and the discharge voltage VDIS. The diodes D1 and D2 may limit the negative voltage swing of the PMOS transistor switch gate during its on-state to avoid damaging the PMOS transistor switch.

As illustrated in FIG. 4(b) a ground switching unit 410 may include a deep n-well (DNW) NMOS transistor switch having a gate coupled to a first terminal of a capacitor C2 and to a switching device 420; a source coupled to a bootstrapping circuit (not shown), a second terminal of the capacitor C2, and a backgate; a drain coupled to a discharge voltage VDIS; and a DNW coupled to a positive supply voltage VDD. The switching device 420 may further be coupled to the discharge voltage VDIS and the supply voltage VDD, and have a control input coupled to a bootstrap controller (not shown). Deep n-well NMOS transistors have an n-type well region formed between a p-type body region and a p-type well region (backgate) for the transistor.

The ground switching unit 410 illustrated in FIG. 4(b) may operate in two phases. In the first operational phase, the DNW NMOS transistor switch may be held in an off-state. Recall, from example of the first operational phase of FIG. 2 that the bootstrap inactivation voltage VBNACT may be applied to the input node N1 of the bootstrapping circuit 210. Thus, the bootstrap inactivation voltage VBNACT may be present at the source of the DNW NMOS transistor switch during the first operational phase of the ground switching unit 410. The switching device 420 may be set to couple the DNW NMOS transistor switch gate to the discharge voltage VDIS and may hold the DNW NMOS transistor switch in an off-state. In an embodiment, the switching device 420 may be configured using transistor switches.

In the second operational phase, the DNW NMOS transistor switch may be set to an on-state for a predetermined time period and may then return to the off-state. The switching device 420 may be set to the positive supply voltage VDD for the predetermined time period. This may set the DNW NMOS transistor switch to an on-state and the charge from the bootstrap inactivation voltage VBNACT may drain to the discharge voltage VDIS. The DNW NMOS transistor switch may remain in an on-state until the switching device 420 may be set to the discharge voltage VDIS for a second predetermined time period and then released, setting the DNW NMOS transistor back to the off-state. The DNW NMOS transistor may held in the off-state by the application of the inverse of the precharge voltage (VPRE of FIG. 2 above) being applied to its source.

In an embodiment, a PMOS transistor switch (not shown) may be implemented in the switching device 420 to the couple the gate of the DNW NMOS transistor to the discharge voltage VDIS. The PMOS transistor switch may have a threshold voltage less than the threshold voltage of the DNW NMOS transistor switch. In such an embodiment, the PMOS transistor switch may hold the DNW NMOS transistor switch at the discharge voltage VDIS until the inverse of the precharge voltage may be applied to the DNW NMOS transistor source. Applying the inverse of the precharge voltage to the DNW NMOS transistor source may cause the PMOS transistor switch to turn off and the DNW NMOS may be held in the off-state.

Several embodiments of the present invention are specifically illustrated and described herein. However, it will be appreciated that modifications and variations of the present invention are covered by the above teachings and within the purview of the appended claims without departing from the spirit and intended scope of the invention.

I claim:

1. A transistor switch controller, comprising:
a capacitor, having a first terminal coupled to a control terminal of the transistor switch to be controlled, and
a switch network, comprising:
a first switch system coupled to the first terminal of the capacitor to selectively supply:
in a first phase of operation, an inactivation voltage sufficient to cause the transistor switch to remain non-conductive, and
at a conclusion of the first phase of operation, a first discharge voltage sufficient to drain the activation voltage from the first terminal of the capacitor, and
a second switch system coupled to a second terminal of the capacitor to selectively supply:
in the first phase of operation, a precharge voltage related to the inactivation voltage, and
in a second phase of operation following the conclusion of the first phase of operation, a second discharge voltage.

2. The transistor switch controller of claim 1, wherein the inactivation voltage is at least a threshold voltage VT of the transistor switch to be controlled.

3. The transistor switch controller of claim 2, wherein the precharge voltage is at least a 2VT.

4. The transistor switch controller of claim 1, the first switching system further comprising:
a first switching unit for coupling the inactivation voltage to the first terminal of the capacitor; and
a ground switching unit for coupling the first discharge voltage to the first terminal of the capacitor.

5. The transistor switch controller of claim 1, wherein:
the transistor switch to be controlled is a PMOS transistor switch,
the inactivation voltage is a threshold voltage VT of the PMOS transistor switch, and
the precharge voltage is at least 2VT.

6. The transistor switch controller of claim 5, wherein the first and second discharge voltage both are ground.

7. The transistor switch controller of claim 5, wherein, during the second phase of operation, the capacitor induces a voltage of at least −2VT on the control terminal of the control terminal of the PMOS transistor switch.

8. The transistor switch controller of claim 1, wherein:
the transistor switch to be controlled is an NMOS transistor switch,
the inactivation voltage is a threshold voltage −VT of the NMOS transistor switch, and
the precharge voltage is at least −2VT.

9. The transistor switch controller of claim 8, wherein the first and second discharge voltage both are ground.

10. The transistor switch controller of claim 8, wherein, during the second phase of operation, the capacitor induces a voltage of at least 2VT on the control terminal of the NMOS transistor switch.

11. A method for controlling a transistor switch to switch from an off-state to an on-state using a transistor switch controller, comprising:
charging a capacitor to an activation potential;
connecting a control terminal for the transistor switch to an inactivation voltage;
connecting the control terminal to a first discharge voltage for a predetermined period of time;
disconnecting the control terminal from the first discharge voltage following the expiration of the predetermined period of time; and
reversing the capacitor charge to a second discharge voltage.

12. The method of claim 11, wherein the inactivation voltage is at least a threshold voltage VT of the transistor switch being controlled.

13. The method of claim 12, wherein the activation potential is at least a 2VT.

14. The method of claim 11, wherein:
the transistor switch being controlled is a PMOS transistor switch,
the inactivation voltage is a threshold voltage VT of the PMOS transistor switch, and
the activation potential is at least 2VT.

15. The method of claim 14, wherein the first and second discharge voltage both are ground.

16. The method of claim 11, wherein:
the transistor switch being controlled is an NMOS transistor switch,
the inactivation voltage is a threshold voltage −VT of the NMOS transistor switch, and
the activation potential is at least −2VT.

17. A ground switching unit for discharging a voltage from a first transistor switch control terminal, comprising:
a second transistor switch for coupling the control terminal to a discharge voltage.

18. The ground switching unit of claim 17, wherein the second transistor switch is a PMOS transistor switch.

19. The ground switching unit of claim 17, the PMOS transistor switch further comprising:
a gate coupled to a first terminal of a first resistor and a first terminal of a first capacitor;
a source coupled to the first transistor switch control terminal;
a drain coupled to the discharge voltage;
a second terminal of the first resistor coupled to a first inactivation voltage; and
a second terminal of the first capacitor coupled to a switching device, wherein the switching device is coupled to a positive supply voltage and the discharge voltage.

20. The ground switching unit of claim 19, further comprising:
a backgate coupled to a first terminal of a second capacitor and a first terminal of a second resistor;
a second terminal of the second capacitor coupled to the PMOS transistor switch gate; and
a second terminal of the second resistor coupled to a second inactivation voltage.

21. The ground switching unit of claim 19, wherein the first inactivation voltage is less than a threshold voltage VT of the transistor switch and greater than the discharge voltage.

22. The ground switching unit of claim 19, wherein the second inactivation voltage is at least a threshold voltage VT of the PMOS transistor.

23. The ground switching unit of claim 17, wherein the second transistor switch is a deep n-well NMOS transistor switch.

24. The ground switching unit of claim 23, the deep n-well NMOS transistor switch further comprising:
a gate coupled to a first terminal of a capacitor and to a switching device;
a source coupled to the first transistor switch control terminal and to a backgate of the deep n-well NMOS transistor switch;
a drain coupled to the discharge voltage;
a deep n-well coupled to a positive supply voltage; and
the switching device coupled to the positive supply voltage and the discharge voltage.
